(19) United States
(12) Patent Application Publication
(10) Pub. No.: US 2008/0157267 A1
(43) Pub. Date: Jul. 3, 2008

(54) Stacked Printed Devices on a Carrier Substrate

(75) Inventors: Mark Gerber, Lucas, TX (US); Wyatt Huddleston, San Diego, CA (US)

Correspondence Address: TEXAS INSTRUMENTS INCORPORATED, P O BOX 655474, M/S 3999, DALLAS, TX, 75265, US

(73) Assignee: Texas Instruments, Dallas, TX (US)

(21) Appl. No.: 11/680,503

(22) Filed: Feb. 28, 2007

Related U.S. Application Data
(60) Provisional application No. 60/877,787, filed on Dec. 29, 2006.

(51) Int. Cl. H01L 29/00; H01L 21/66

(52) U.S. Cl. 257/528; 438/17; 257/E29.001; 257/E21.521

(57) ABSTRACT

Disclosed herein are systems and methods for stacking passive component devices on a substrate. A conductive material is printed onto a first substrate using a fluid ejection device to form a printed passive device according to a predetermined design. The first substrate is attached to a second substrate, such as a die, to form a component for performing a predetermined function. The component may then be tested to determine whether the component formed according to the predetermined design performs the predetermined function. The design may be adjusted in response to the test to improve the performance of the component in performing the predetermined function. Multiple substrates having printed passive devices may be stacked and electrically connected to the die or other substrate in order to increase the number of devices formed on a particular area of that die or other substrate.

### RELATED APPLICATION

The present application claims priority under 35 U.S.C. §119(e) to U.S. provisional application No. 60/877,787, filed Dec. 29, 2006.

### BACKGROUND

Electronic devices, such as computers, wireless telephones, personal digital assistants, audio/video devices, etc. include integrated circuits (IC) chips that provide active and passive devices. The chip may be bound to a printed circuit board or substrate which connects the product chip to other product chips and/or to system components (e.g., processors, memory, etc) of the device.

The processes for creating the passive and active devices using semiconductors include expensive and time consuming processes and techniques, including masking, etching, and high temperature steps. Additionally, aspects of the processes specific to creating the active devices are incompatible with those specific to creating passive devices. For example, the high temperature processes involved in creating thin dielectrics and other passive features may cause other deleterious effects, and may even destroy active components such as a transistor. Still further, when a given IC product is being developed using masking techniques, a different mask may have to be developed for each iteration of a design modification.

### SUMMARY

Embodiments of the present disclosure include systems and methods for creating a stack of printed passive devices.

According to one implementation a method is disclosed for creating a stacked passive device on a die. A conductive material is printed onto a first substrate to form a printed passive device according to a predetermined design. The first substrate is attached to a second substrate, such as a die, to form a component for performing a predetermined function. The component may then be tested to determine whether the component formed according to the predetermined design performs the predetermined function. The design may be adjusted in response to the test to improve the performance of the component in performing the predetermined function. An adjusted component may be created by printing a conductive material on a third substrate to form a passive device according to the adjusted design and attaching the third substrate to a forth substrate to form the adjusted component for performing the predetermined function.

Multiple substrates having printed passive devices may be stacked and electrically connected to the die or other substrate in order to increase the number of devices formed on a particular area of that die or other substrate.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a perspective view of stacked passive devices that are printed using digital techniques.

FIG. 2 shows is a flow diagram that describes steps in a method of testing a design for a printed passive device stacked on a die, and modifying the design in response to the test.

FIG. 3 shows a top plan view of an exemplary device having printed passive devices on a carrier substrate and electrical connections to a die or other substrate.

FIG. 4 shows a cross-sectional view taken along line 4-4 of FIG. 3.

FIG. 5 shows a cross-sectional view of an alternative implementation in which solder balls and/or an adhesive layer may be used to connect the passive device carrier substrate to the die.

FIG. 6 shows a cross-sectional view of another alternative implementation in which a surface of the passive device carrier substrate having passive devices faces the die.

FIG. 7 shows a cross-sectional view of another alternative implementation in which both wire bonds and solder balls are employed to connect two opposing sides of the passive device carrier substrate to the die.

FIG. 8 shows a cross-sectional view of another alternative implementation in which two passive device carrier substrates are stacked so that the passive devices on one passive device carrier substrate face toward the die and the passive devices on a second passive device carrier substrate face away from the die.

FIG. 9 shows a cross-sectional view of another alternative implementation in which two passive device carrier substrates are stacked and wire bonded to the die.

FIG. 10 shows a cross-sectional view of another alternative implementation in which multiple passive device carrier substrates are stacked and electrical connections are established through wire bonds and solder balls.

### DETAILED DESCRIPTION

Systems and methods for creating a stacked printed passive device will now be described with more particularity and with reference to the drawings.

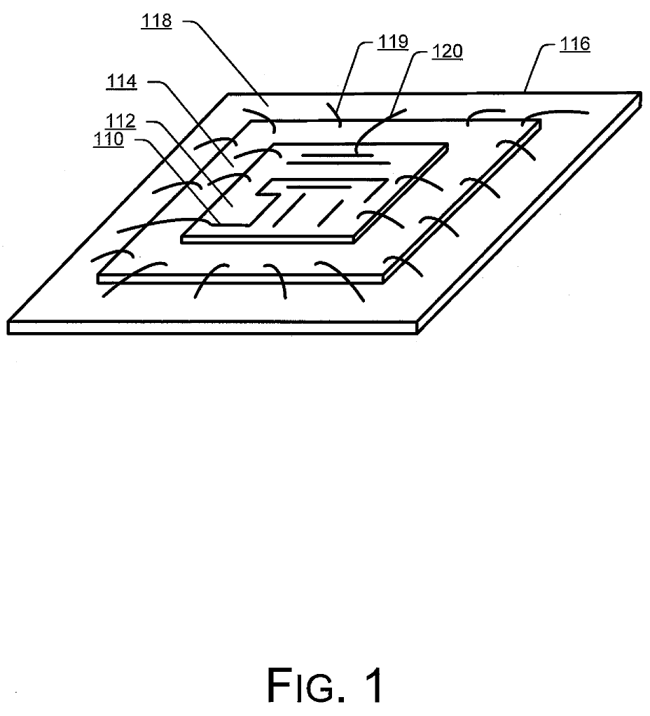

FIG. 1 shows a stack of substrates including printed passive devices. One or more passive devices 110 may be printed on passive device carrier substrate 112, which may be any suitable inorganic or organic substrate, such as a laminate, circuit board, polymeric tape, resin impregnated glass fiber matrix (commonly referred to as “FR4”), ceramic or the like. The one or more passive devices 110 may be inductors, capacitors, resistors, diodes and/or multilevel interconnects. The passive devices 110 and/or circuit may be designed as one or more deposited layers using a design mechanism that is physically and/or electrically connected to the fluid ejection device. For example, the design mechanism may be a computing device, such as a computer, tablet, or the like. The computing device may direct the fluid ejection device to print the design in a manner similar in nature to an inkjet printing device. The fluid ejection device may deposit one or more layers in order to create one or more printed passive devices 110 on the passive device carrier substrate 112. Fluid ejection printing may allow the user to quickly create passive devices and circuits without requiring masking, etching, vapor deposition or other techniques, which are relatively expensive and time consuming.

The fluid ejection device may be any suitable device for the deposition of conductive and dielectric printing, particularly those that that do not require expensive and time consuming mask creation procedures. For example, the fluid ejection device may have thermal or piezoelectric print heads to serve as a “drop-on-demand” mechanism. A temperature-controlled vacuum chuck may be employed so that drops may be deposited onto a heated substrate with a relatively high level of precision. One exemplary fluid ejection printing device is the Dimatix® Materials Printer manufactured by FUJIFILM Dimatix, of Santa Clara, Calif., USA. The conductive materials deposited may be silver, gold, copper, or other suitable conductive materials including metals and alloys. A solvent may be used to deliver the material from the print head in a liquid form. As the conductive material in solution is deposited on the heated substrate, or in a heated environment, the solvent used in the deposition of the conductive material evaporates or burns off and the conductive particles anneal together to form the conductive pattern.

The fluid ejection device may also be used to deposit dielectric materials. Exemplary dielectric materials include polyimide, benzocyclobutene (BCB), or other suitable insulating material.

The passive device carrier substrate 112 may be attached to a die 114, such as a semiconductor die. The die 114 may also carry active devices, circuitry or other carrier substrates. The passive device carrier substrate 112 may be attached using an epoxy or adhesive layer. Additionally or alternatively, the passive device carrier substrate 112 and die 114 may be electrically connected using wire bonding and/or solder ball techniques. For example, wire bond 116 may electrically connect the passive device carrier substrate 112 to the die 114. The passive device carrier substrate 112 and die 114 may be encapsulated as a package to reduce or eliminate detrimental environmental effects. The passive device carrier substrate 112 and die 114 may be used as a component of a larger system by electrically connecting the package to a base substrate 118. The passive device carrier substrate 112 and/or passive devices therein may be directly connected to the base substrate 118 by wire bonds 120 or other suitable connection means.

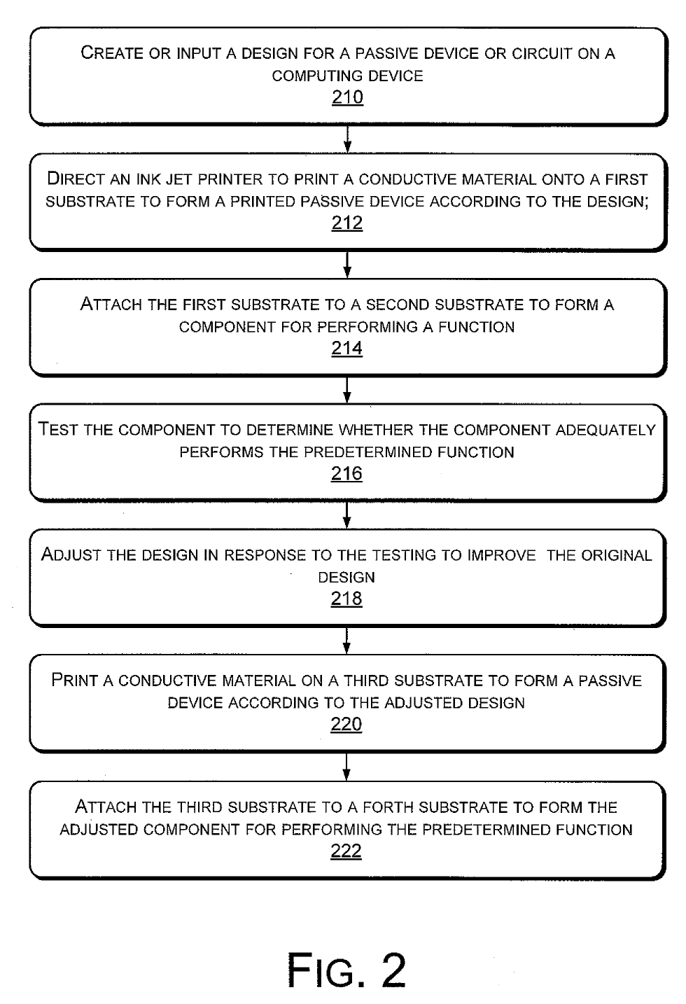

A method of manufacturing stacked passive devices may be shown by way of the flowchart in FIG. 2 and with reference to the stacked device shown in FIG. 1. A circuit design incorporating passive devices 110 or a design of discrete passive devices 110 may be created or input into a computing device (Block 210). The computing device may be used to direct a fluid ejection device to deposit conductive and/or insulating materials onto an organic or inorganic passive device carrier substrate 112 to create the passive devices 110 and/or circuit according to the design created or input (Block 212).

The passive device carrier substrate 112 may be physically and/or electrically connected to a die 114 (Block 214). The die 114 may have other passive or active carrier substrates connected thereto. The die 114 may be connected to circuitry on a base substrate 118 by wire bonds 119 or other connection means.

The passive devices and/other circuitry may be tested (Block 216) to determine if the printed passive devices 110 and/or circuit adequately perform the function or functions as per the design created or input (Block 210). The testing may be conducted on the passive device carrier substrate 112 before or after it is connected to the die 114 or other passive device carrier substrates, as described below. The passive carrier substrates and die may also be tested before or after connecting the passive carrier substrates and die to the base substrate. According to one example, the passive devices 110 on the passive carrier substrate 112 may be tested using well known techniques such as an open/short or flying probe test. Additionally or alternatively, testing may be performed using a tester that measures specific values for resistors, capacitors, and/or inductors. The passive device carrier substrate 112, the die 114, and or the base substrate 118 may also be encapsulated prior to testing.

If it is determined through testing that the printed design is not performing as intended (Block 216), the design may be modified or adjusted (Block 218). Thus, for example, if an engineer or technician determines that the inductance obtained by a printed inductor does not meet the requirements of a particular circuit design, the design can be altered so that the inductor is made shorter or longer to achieve the desired inductance value. A new printed passive device carrier substrate 112′ can be printed with one or more passive devices 110 according to the adjusted design (Block 220). The adjusted design may be a minor iteration of the original design or may be a significant design change based on the results of testing the passive device carrier substrate 112. The printed passive carrier substrate 112′ may replace the original printed passive carrier substrate 112 on the original die 114 or may be attached to a new die for further testing or insertion in a final application (Block 222).

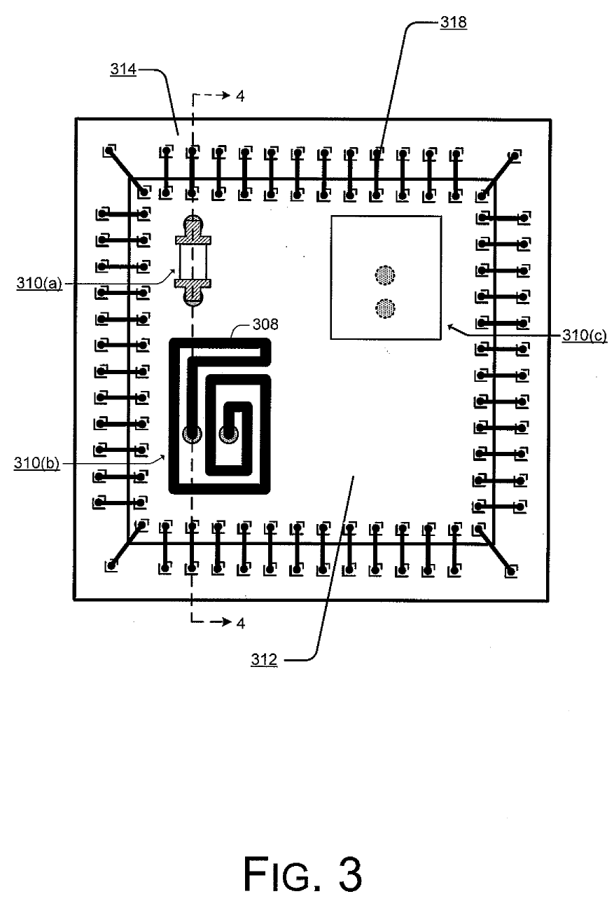

FIG. 3 shows a top plan view of a device having a carrier substrate stacked upon a die. Passive devices such as a resistor 310a, inductor 310b, and/or capacitor 310c may be printed on the surface of a passive device carrier substrate 312 in the manner described above. Conductive traces, which are not illustrated in FIG. 3 for the sake of simplicity, may be formed on the front or back side of the printed passive device carrier substrate 312. The printed passive device carrier substrate 312 may be connected to die 314 by wire bonds 318.

With reference to FIGS. 3-10, it is noted that the passive devices, substrates and other features are shown exaggerated for illustrative purposes and are not intended to reflect a scale. Furthermore, portions of the circuitry have been omitted from the drawings for the sake of simplicity.

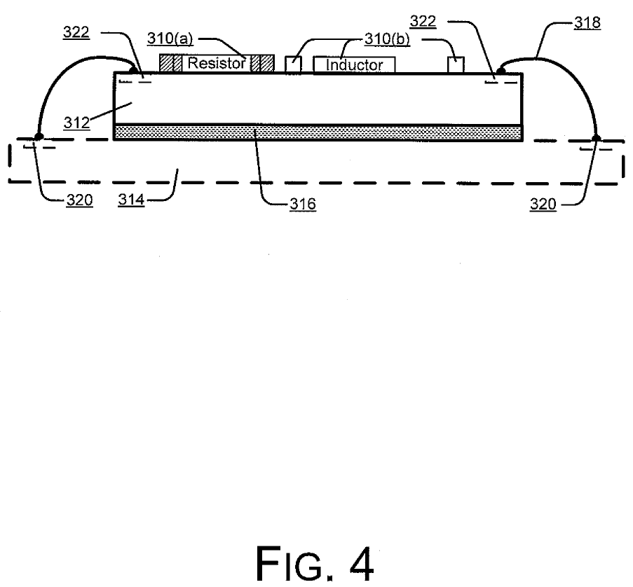

FIG. 4 illustrates a cross-section taken along line 4-4 in FIG. 3 and more clearly shows the attachment of the printed passive device carrier substrate 312 on die 314. The printed passive device carrier substrate 312 may be attached to a die 314 using an adhesive 316, such as an epoxy adhesive. Adhesive layer 316 may encapsulate any layers or devices on the backside of passive device carrier substrate. Electrical connections may be made by connecting wire bonds 318 to bonding pads 320 and 322. The bonding pads 320 and 322 may be connected to further circuitry, which is not illustrated for the sake of simplicity as indicated above.

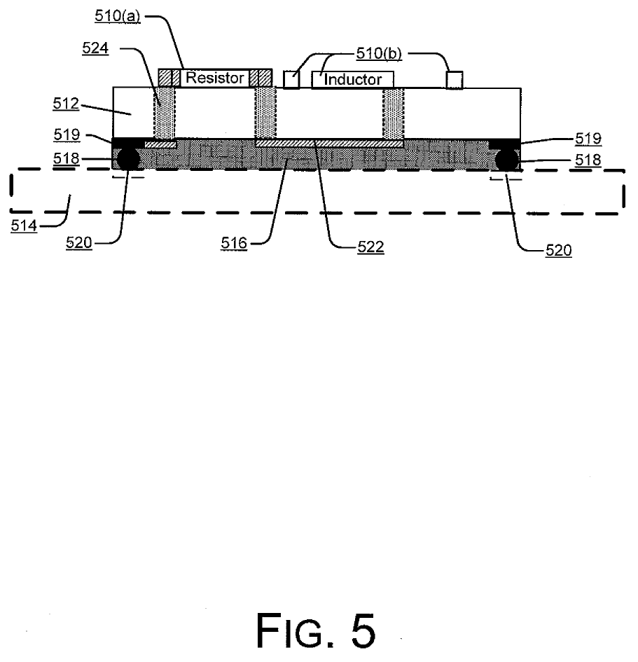

FIG. 5 shows a cross-sectional view of an alternative implementation in which solder balls and/or an adhesive layer may be used for connection. Solder balls 518 may be connected to bond pads 519 disposed on or within printed passive device carrier substrate 512 and bond pads 520 disposed on or within die 514. An adhesive layer 516 may be used to attach printed passive device carrier substrate 512 to die 514. The adhesive layer 516 may encapsulate any devices or layers, such as conductive traces 522 or solder balls 518, on the backside of the printed passive device carrier substrate 512. The devices or layers on the backside maybe connected to the passive devices through vias 524.

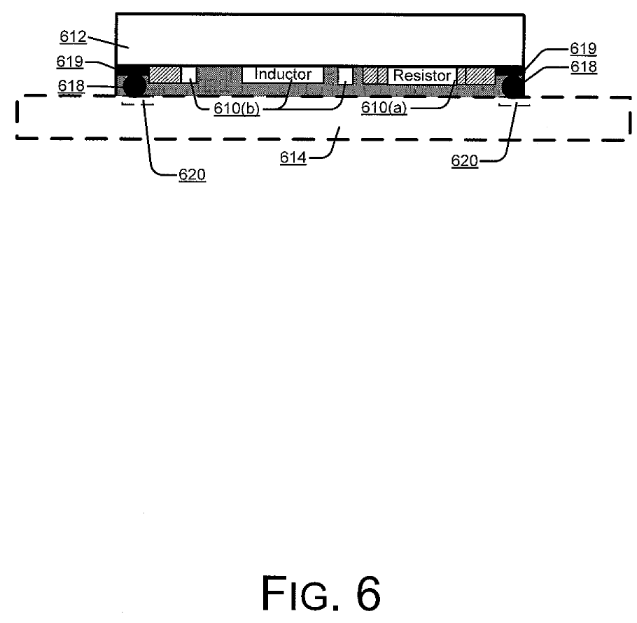

FIG. 6 shows a cross-sectional view of another alternative implementation in which a side of the printed passive device carrier substrate 612 having passive devices (e.g., 610(a) and 610(b)) is placed facing die 614. Electrical connection is established through solder balls 618, which may be connected to bond pads 619 and disposed on or within printed passive device carrier substrate 612 and bond pads 620 disposed on or within die 614. As above, the bonding pads 619 and 620 may be connected to further circuitry, which is not illustrated for the sake of simplicity.

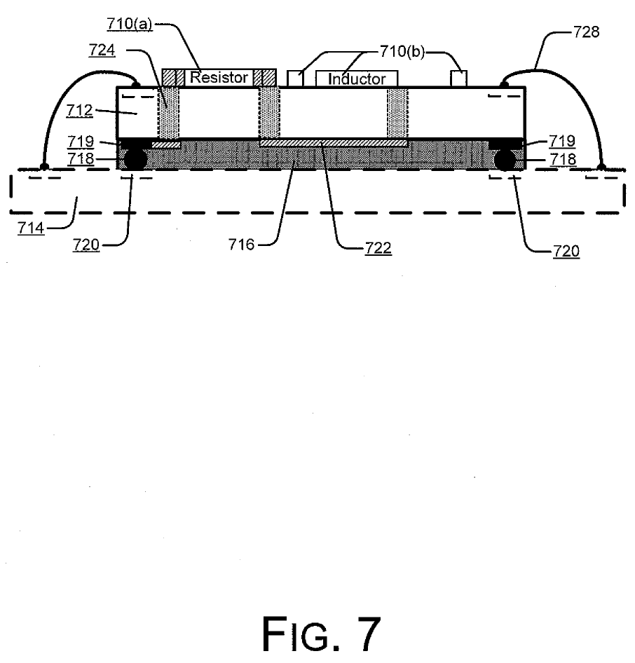

FIG. 7 shows a cross-sectional view of another alternative implementation in which both wire bonds 728 and solder balls 718 are employed to connect both sides of the printed passive device carrier substrate 712 having printed passive devices (e.g., 710(a) and 710(b)). Electrical connection is established through solder balls 718, which may be connected to bond pads 719 and disposed on or within printed passive device carrier substrate 712 and bond pads 720 disposed on or within die 714. The bonding pads 719 and 720 may be connected to further circuitry, which is not illustrated for the sake of simplicity. The two sides of passive device carrier substrate 724 having circuitry may be connected by vias 724.

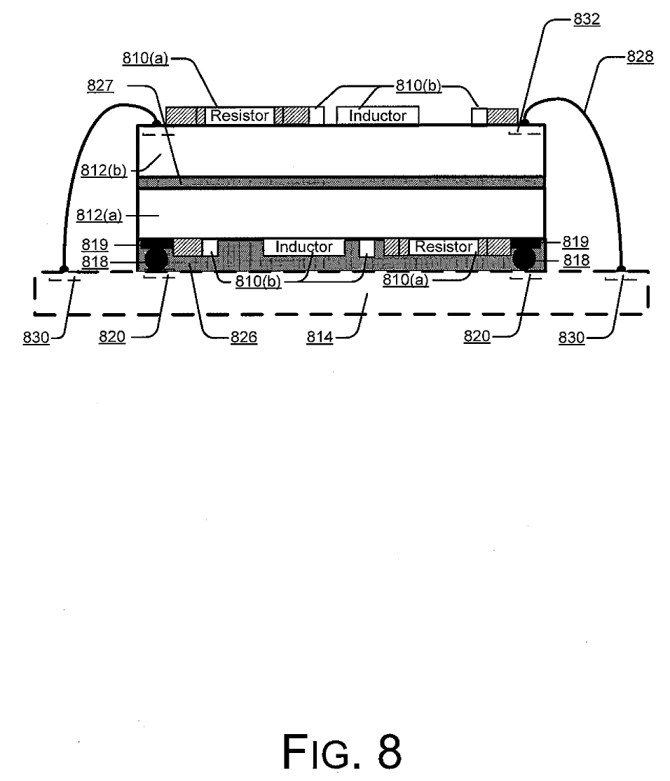

FIG. 8 shows a cross-sectional view of another alternative implementation in which two printed passive device carrier substrates are formed as a stack. Printed passive device carrier substrate 812(a) is placed with passive devices and/or circuitry facing toward die 814. Printed passive device carrier substrate 812(b) is placed with the passive devices facing away from the die. Substrate 812(a) may be adhered to die 814 by adhesive layer 826. Adhesive layer 827 may connect substrate 812(b) and 812(a). The adhesive layers 826 and 827 may provide environmental protection of the passive devices 810(a), 810(b), and any other circuitry underlying the adhesive layers. The substrates 812(a) and 812(b) and die 814 may be adhered in any order. Thus, for example, substrate 812(a) may be adhered to die 814 before or after being adhered to substrate 812(b).

Solder balls 818 are employed to connect die 814 to printed passive device carrier substrate 812(a). Wire bonds 828 may provide electrical connection between die 814 and printed passive device carrier substrate 812(b). The solder balls 818 may be connected to bond pads 819 disposed on or within printed passive device carrier substrate 812(a) and to bond pads 820 disposed on or within die 814. The wire bonds may be connected to wire bond pads 830 and 832 disposed on or within die 814. The bonding pads 819, 820, 830, and 832 may be connected to further circuitry, which is not illustrated for the sake of simplicity.

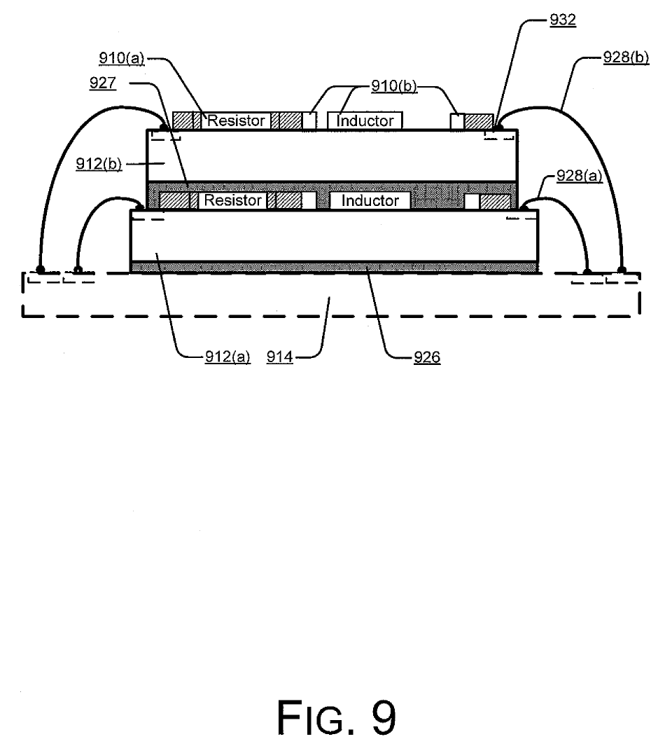

FIG. 9 shows a cross-sectional view of another alternative implementation in which two printed passive device carrier substrates are stacked and wire bonded to the die. Printed passive device carrier substrate 912(a) may be attached to the die 914 by adhesive layer 926. Printed passive device carrier substrate 912(b) may be attached to the printed passive device carrier substrate 912(a) by adhesive layer 927. Wire bonds 928(a) and 928(b) may provide electrical connection between substrates 912(a), 912(b) and the die 914.

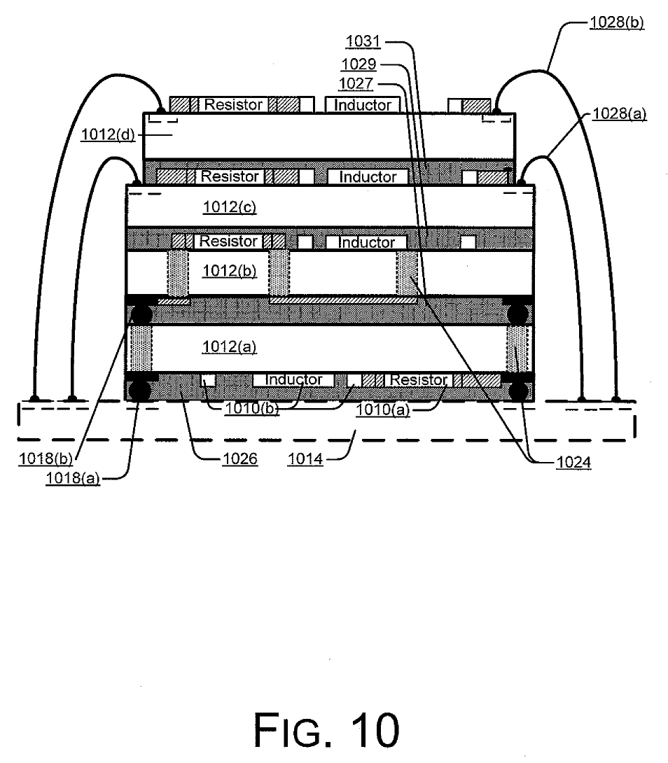

FIG. 10 shows another cross-sectional view of an alternative implementation in which multiple printed passive device carrier substrates are stacked. Passive device carrier substrate 1012(a) may be connected to die 1014 by adhesive layer 1026, such as an epoxy or other suitable layer. Solder balls 1018(a) may provide electrical connection. Passive device carrier substrate 1012(b) may be attached to passive device carrier substrate 1012(a) by another adhesive layer 1027, which may also be an epoxy or other suitable layer. Electrical connection between the printed passive device carrier substrate 1012(b) and die 1014 may be established with solder ball connections 1018(b) and 1018(a) and vias 1024.

Wire bonded devices may also be stacked with printed passive device carrier substrates 1012(a) and 1012(b). For example, printed passive device carrier substrate 1012(c) may be attached to printed passive device carrier substrate 1012(b) by adhesive layer 1029, such as an epoxy or other suitable layer. Electrical connection between the printed passive device carrier substrate 1012(c) and die 1014 may be established with wire bonds 1028(a). Printed passive device carrier substrate 1012(d) may be attached to printed passive device carrier substrate 1012(c) by adhesive layer 1031, which may also be an epoxy or other suitable layer. Electrical connection between the printed passive device carrier substrate 1012(c) and die 1014 may be established with wire bonds 1028(b). Printed passive device carrier substrate 1012(d) may be made slightly smaller than printed passive device carrier substrate 1012(c) to accommodate the wire bond connections. Adhesive layers 1026, 1027,1029, and 1031 may encapsulate passive devices and/or circuitry on the surfaces of the printed passive device substrates.

Stacking multiple substrates with passive devices allows more passive devices to be formed using the same amount of surface space on the base substrate. FIG. 10 shows four printed passive device carrier substrates stacked together, but it is conceived that any number of passive device carrier substrates may be formed upon die 1014 in accordance with this disclosure. Furthermore, though solder ball and wire bond connections are shown in FIGS. 3-10, it should be understood that any electrical connection may be utilized. For example, the electrical connection may be established using lead frame or other suitable technology. It is also noted that the implementations described herein may also be partially or entirely encapsulated to provide environmental protection.

Although the invention has been described in language specific to structural features and/or methodological steps, it is to be understood that the invention defined in the appended claims is not necessarily limited to the specific features or steps described. Rather, the specific features and steps are disclosed as preferred forms of implementing the claimed invention.

1. A method for creating a stacked passive device on a semiconductor die, the method comprising:
printing a conductive material onto a first substrate using a fluid ejection printing device to form a printed passive device according to a predetermined design;
attaching the first substrate to a second substrate to form a component for performing a predetermined function;
testing the component to determine whether the component formed according to the predetermined design performs the predetermined function;
adjusting the design in response to the test to improve the performance of an adjusted component in performing the predetermined function;
printing a conductive material on a third substrate using a fluid ejection printing device to form a passive device according to the adjusted design; and
attaching the third substrate to a forth substrate, the third and forth substrate replacing the first and second substrate component for performing the predetermined function.

2. A method according to claim 1, further comprising attaching and electrically connecting the forth substrate to a base substrate.

3. A method according to claim 2, further comprising electrically connecting the third substrate to the base substrate by attaching one end of a wire to the third substrate and the other end of the wire to the base substrate.

4. A method according to claim 1, further comprising encapsulating the third substrate and the fourth substrate.

5. A device made according to the method of claim 1.

6. A device according to claim 5, wherein the first and third substrates are printed passive device carrier substrates and the second and forth substrates are die, and wherein one or more additional printed passive device carrier substrates are formed upon the third passive device carrier substrate and electrically connected to the die.

7. A device comprising:
a first printed passive device carrier substrate having a fluid ejection printed passive device layer, the first printed passive device carrier substrate connected to a die or a base substrate; and
a second printed passive device carrier substrate having a fluid ejection printed passive device layer, the second printed passive device carrier substrate disposed upon the first printed passive device carrier substrate and connected to the first printed passive device carrier substrate, the die, or the base substrate.

8. The device of claim 7, wherein the die is formed on the base substrate and the first printed device is formed on the die.

9. The method according to claim 7, wherein the substrate is an organic substrate.

10. A method for creating a stacked passive device comprising:
printing a pattern of at least one material on a carrier substrate using a fluid ejection device to form one or more printed passive devices,
connecting the printed passive device on the carrier substrate to a die surface; and
environmentally isolating the package having the carrier substrate and die.

11. The method according to claim 10, further comprising attaching the die to a base substrate.

12. The method according to claim 10, wherein connecting comprises physically attaching the carrier substrate to the die and electrically coupling the passive device to an active device on the die.

13. The method according to claim 10, wherein the substrate is an organic substrate.

14. The method according to claim 10, wherein the carrier substrate is a first carrier substrate and further comprising:
printing a pattern of at least one material on a second carrier substrate using a fluid ejection device to form one or more printed passive devices;
attaching the second carrier substrate to the first second carrier substrate; and
electrically connecting the second carrier substrate to the first carrier substrate or the die surface.

15. The method according to claim 11, further comprising electrically connecting the printed passive device to the base substrate.

16. The method according to claim 11, further comprising electrically connecting the die to the base substrate.

17. The method according to claim 10, wherein environmentally isolating the die and passive device comprises encapsulating the die and passive device in an encapsulation layer.

18. The method according to claim 10, wherein printing is performed using a thermal or piezoelectric fluid ejection printing device.

19. The method according to claim 10, wherein the printed pattern consists of multiple overlapping printed layers deposited by the fluid ejection printing device.

20. The method according to claim 11, further comprising testing the electrical properties of the printed pattern using a flying probe tester.
